(19) United States
(12) Patent Application Publication
(10) Pub. No.: US 2010/0193879 A1
(43) Pub. Date: Aug. 5, 2010

(54) Isolation Region Implant and Structure

(76) Inventors: Ming-Han Liao, Taipei City (TW); Tze-Liang Lee, Hsin-Chu (TW)

Correspondence Address: SLATER & MATSIL, L.L.P., 17950 PRESTON ROAD, SUITE 1000, DALLAS, TX, 75252, US

(21) Appl. No.: 12/617,515

(22) Filed: Nov. 12, 2009

Related U.S. Application Data
(60) Provisional application No. 61/150,220, filed on Feb. 5, 2009.

(51) Int. Cl. H01L 27/088; H01L 21/336

(52) U.S. Cl. 257/392; 438/289; 257/E21.409; 257/E27.061

(57) ABSTRACT

A method and structure for modulating the threshold voltage of transistor is provided. An opening for an isolation region is formed within a substrate using a masking layer. The masking layer is then pulled back from the opening, and dopants are implanted into the substrate through the exposed surface of the substrate and the sidewalls of the opening. This implantation can be tailored to modulate the threshold voltage of transistors with smaller gate widths without modulating the threshold voltage of other transistors with larger gate widths.

This application claims the benefit of U.S. Provisional Patent Application Ser. No. 61/150,220, filed on Feb. 5, 2009, and entitled “Isolation Region Implant and Structure,” which application is incorporated herein by reference.

### TECHNICAL FIELD

The present invention relates generally to a system and method for manufacturing semiconductor devices and, more particularly, to a system and method for forming transistors with shallow trench isolation.

### BACKGROUND

Generally, semiconductor devices such as transistors are formed by first isolating active areas of a substrate using such isolation structures as shallow trench isolations (STIs). Once active regions have been isolated, a variety of structures are built above the substrate (such as gate dielectrics and gate electrodes) and a variety of dopants are implanted into the substrate in order to complete the device. However, as the size of the devices have been scaled down in order to accommodate more devices on smaller chips, serious problems have arisen due to short channel effects.

One such problem is an abnormal rise that is seen in the threshold voltage as the width of a transistor's gate is reduced. Such an increase in the threshold voltage can cause the device to exceed its desired design parameters during operation, and can negatively influence the overall design of the device in general. This type of problem may reduce the performance of the device and reduce the overall efficiency of the desired chip.

Additionally, this increase in the threshold voltage of the narrower transistors can also cause problems when transistors of various sizes are integrated into the same system. Because transistors with wider gates do not experience the same abnormal increase in threshold voltage, multiple devices that were initially designed and integrated to have similar voltages might have very different actual threshold voltages when actually manufactured. If these disparate devices where designed to function with the same threshold voltage, such a situation can immediately cause problems during operation of the devices in conjunction with each other. Additionally, some solutions to this problem that work to reduce the threshold voltage of the scaled down transistor would also reduce the threshold voltage of the non-scaled down transistors, thereby failing to solve the problems of the devices having different threshold voltages.

As such, what is needed is a mechanism to solve the above deficiencies.

### SUMMARY OF THE INVENTION

These and other problems are generally solved or circumvented, and technical advantages are generally achieved, by embodiments of the present invention that allow for a modulation of the threshold voltage of certain semiconductor devices.

In accordance with an embodiment of the present invention, a method for manufacturing isolation regions comprises providing a substrate and forming a patterned mask over the substrate, the patterned mask exposing a portion of the substrate. A portion of the substrate is removed to form a trench. A portion of the patterned mask adjacent to the trench is removed to form an exposed surface of the substrate, and a first dopant with a first conductivity is implanted into the substrate. The patterned mask is removed after the implanting the first dopant, and the trench is filled with a dielectric material.

In accordance with another embodiment of the present invention, a method of manufacturing a semiconductor device comprises providing a substrate comprising a top surface and forming a trench in the substrate, wherein the forming the trench comprises forming a masking layer over the substrate, forming an opening through the masking layer, and removing a portion of the substrate through the opening. After the forming the trench, the opening through the masking layer is expanded to form an exposed portion of the top surface of the substrate, and a first dopant with a first conductivity is implanted into the substrate prior to removing the masking layer.

In accordance with yet another embodiment of the present invention, a semiconductor device comprises a substrate with a top surface and a first isolation region within the substrate. A first doped region is located adjacent to the isolation region, and the first doped region comprises a first dopant with a first conductivity and a first concentration. A first channel region is located on the substrate separated from the first isolation region. A second doped region is located between the first doped region and the first channel region, the second doped region comprising a second dopant with a second conductivity and a second concentration less than the first concentration.

An advantage of an embodiment of the present invention allows for the modulation of the threshold voltages of certain transistors.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a substrate with a masking layer exposing a trench that separates active areas on a surface of the substrate in accordance with an embodiment of the present invention;

FIG. 2 illustrates a pullback of the masking layer to expose a top surface of the substrate adjacent to the opening and an implantation step to form modulation regions in accordance with an embodiment of the present invention;

FIG. 3 illustrates the filling of the opening with a dielectric in accordance with an embodiment of the present invention;

FIG. 4 illustrates the formation of a transistor over the active region of the substrate in accordance with an embodiment of the present invention;

FIGS. 5A-5B illustrate overhead views of transistors utilizing the modulation regions in accordance with an embodiment of the present invention; and

FIGS. 6A-6D illustrate the adjustments that may be realized with the inclusion of the modulation regions in accordance with an embodiment of the present invention.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION OF ILLUSTRATIVE EMBODIMENTS

The making and using of embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to embodiments in a specific context, namely a manufacturing process of a transistor which includes an additional implantation step.

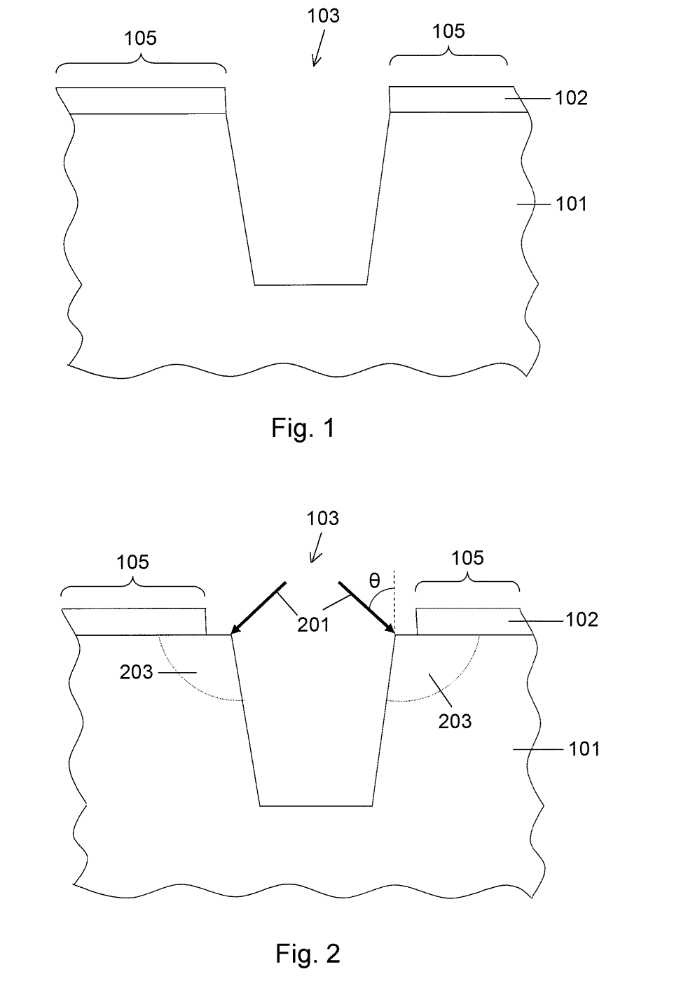

With reference to FIG. 1, there is shown the formation of a trench 103 between active areas 105 in a substrate 101 using a masking layer 102. The substrate 101 may comprise bulk silicon, doped or undoped, or an active layer of a silicon on insulator (SOI) substrate. Generally, an SOI substrate comprises a layer of a semiconductor material such as silicon, germanium, silicon germanium, silicon germanium on insulator (SGOI), or combinations thereof. Other substrates that may be used include multi-layered substrates, gradient substrates, or hybrid orientation substrates.

The active areas 105 are areas of the substrate 101 adjacent to the top surface of the substrate 101 into which dopants will later be implanted in order to make the active areas 105 conductive. The active areas 105 will be used to form active devices such as transistors, resistors, etc. (described below in greater detail beginning with FIG. 4).

The masking layer 102 is formed and patterned over the substrate 101 to protect the active areas 105 while exposing portions of the substrate 101 to assist in the formation of the trench 103. The masking layer 102 is formed by depositing a hardmask layer comprising silicon nitride formed through a process such as chemical vapor deposition (CVD), although other materials, such as oxides, oxynitrides, silicon carbide, combinations of these, or the like, and other processes, such as plasma enhanced chemical vapor deposition (PECVD), low pressure chemical vapor deposition (LPCVD), or even silicon oxide formation followed by nitridation, may alternatively be utilized. Once formed, the hardmask layer is patterned through a suitable photolithographic process to expose those portions of the substrate 101 as illustrated in FIG. 1.

Once the masking layer 102 has been formed and patterned, the trench 103 is formed in the substrate 101. The exposed substrate 101 is removed through a suitable process such as reactive ion etching (RIE) in order to form the trench 103 in the substrate 101, although other suitable processes may alternatively be used. The trench 103 is formed to be between about 2,400 Å and about 5,000 Å in depth from the surface of the substrate 101, such as about 3,000 Å.

As one of skill in the art will recognize, however, the processes and materials described above to form the masking layer 102 are not the only method that may be used to protect the active areas 105 while exposing portions of the substrate 101 for the formation of the trench 103. Any suitable process, such as a patterned and developed photoresist, may alternatively be utilized to protect the active areas 105 of the substrate 101 while exposing portions of the substrate 101 to be removed to form the trench 103. All such methods are fully intended to be included in the scope of the present invention.

FIG. 2 illustrates a pullback of the masking layer 102 to expose at least a portion of the top surface of the substrate 101 adjacent the trench 103. The pullback is performed using a dry etch process, such as RIE, and a suitable photolithographic masking technique as is known in the art. The dry etch process uses one or more reactive etchants such as CₓF_{y}, CₓH_{z}F_{y}, SₓF_{y}, NₓF_{y}, combinations of these, or the like, although any suitable gases, such as inert gases like N₂, He, Ne, Ar, Kr, or Xe, or combinations of these, may alternatively be utilized. The pullback of the masking layer 102 exposes between about 10 Å and about 100 Å of the surface of the substrate 101 from the edge of the trench 103, such as about 50 Å.

FIG. 2 also illustrates an implant step (represented by arrows 201 in FIG. 2) to form modulation regions 203. The implant step 201 may be performed in multiple steps using the masking layer 102 as a mask, and implants either n-type dopants (e.g., phosphorous, arsenic, antimony, or the like), or p-type dopants (e.g., BF₂, boron, aluminum, indium, or the like). However, any other suitable ions, such as boron ions or fluorine ions, which may be suitable for adjusting the properties of the to-be formed transistor (described below with respect to FIG. 4), may alternatively be utilized.

Further, while the exact parameters for the implant step 201 are dependant at least in part upon the desired features of the completed device, the implant step 201 may be performed at an implant angle θ of between about 30° and about 50°, such as about 45°, and an implantation power of between about 10 KeV and about 50 KeV, such as about 20 KeV. Further, the additional implantation step 201 is utilized to form a concentration in the modulation regions 203 of between about 1×10¹⁸ cm⁻³ and about 1×10²⁰ cm⁻³, such as about 1×10¹⁹ cm⁻³.

As an illustrative example of an embodiment of the present invention, an n-type transistor having a gate width of about 0.1 μm is desired to be modulated to reduce the threshold voltage. Given this, the implant step 201 may be performed using p-type dopants that may be implanted at an angle of about 45° with an energy of about 20 KeV in order to achieve an initial concentration in the modulation regions 203 (prior to source/drain region implantation) of about 5×10¹⁸ cm⁻³. Using these parameters, the implant step 201 will reduce the threshold voltage of the n-type transistor about 60 meV.

As another illustrative example of the present invention, a p-type transistor having a gate width of about 0.1 μm is desired to be modulated to increase the threshold voltage of the p-type transistor. Given this, the implant step 201 may be performed using p-type dopants that may be implanted at an angle of about 30° with an energy of about 30 keV in order to achieve an initial concentration in the modulation regions 203 (prior to source/drain region implantation) of about 3×10¹⁸ cm⁻³. Using these parameters, the implant step 201 will reduce the threshold voltage of the p-type transistor about 105 keV.

However, it should be noted that the examples specifically described above are merely illustrative of various embodiments of the present invention, and are not meant to be exclusive. Any number of combinations of channel types, dopants, implantation angles, implantation energies, and/or concentrations may be utilized to adjust the properties of the gates of narrow transistors. For example, n-type dopants may be implanted to form modulation regions 203 within a desired p-type transistor in order to reduce the threshold voltage of the p-type transistor, or else p-type dopants may be implanted into a desired n-type transistor in order to reduce the threshold voltage of the n-type transistor. Any suitable combination of these parameters may be utilized to modulate various properties of the device, and all such combinations are fully intended to be included within the scope of the present invention.

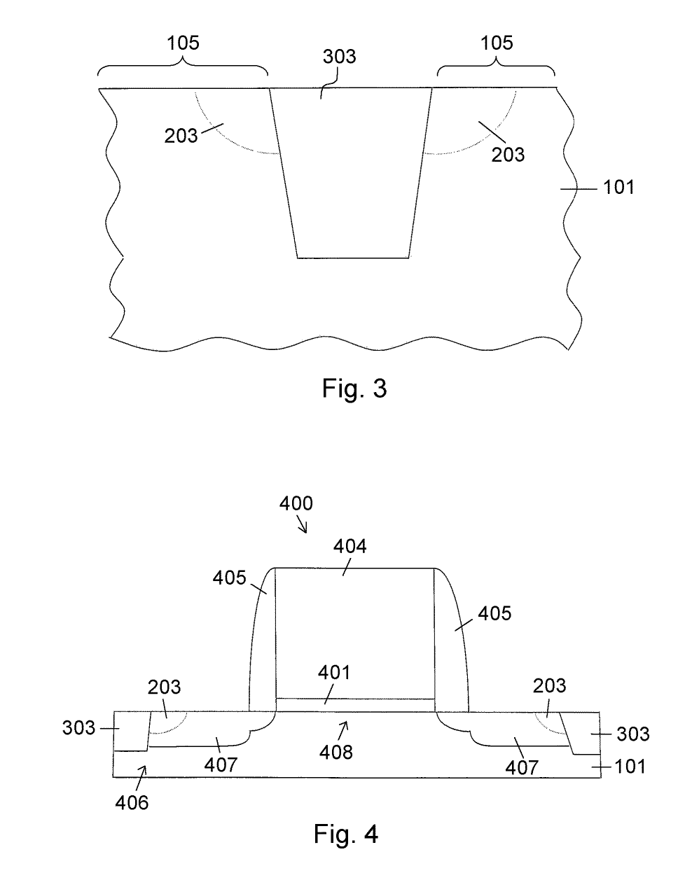

FIG. 3 illustrates the filling of the trench 103 (see FIG. 2) with a dielectric material to form an isolation region 303. The dielectric material may be an oxide material, a high-density plasma (HDP) oxide, or the like. The dielectric material is also formed using either a chemical vapor deposition (CVD) method, such as the High Aspect Ratio Process (HARP) process, a high density plasma CVD method, or other suitable method of formation as is known in the art.

The isolation region 303 is formed by overfilling the trench 103 and the masking layer 102 with the dielectric material and then removing excess material outside of the trench 103 and the masking layer 102 through a suitable process such as chemical mechanical polishing (CMP), an etch, a combination of these, or the like. The removal process may remove the masking layer 102 as well, so as to expose the substrate 101 to further process steps. Optionally, an oxide liner may be formed along the sidewalls of the trench 103 prior to filling the trench 103.

However, one of ordinary skill in the art will recognize that the above described method of filling the trench 103 is only one illustrative method that may be used with the present invention. Any suitable method, including methods with combinations of CMP and etching, or methods involving recessing the dielectric material and refilling the trench 103 may alternatively be utilized. All of these methods are fully intended to be included within the scope of the present invention.

FIG. 4 illustrates the formation of a transistor 400 in the active areas 105 after the formation of multiple isolation regions 303. The transistor 400 comprises a deep well region 406, a channel region 408, a dielectric layer 401, a gate electrode 404, spacers 405, and source/drain regions 407. The deep well region 406 may be formed by the implantation of suitable materials into the substrate 101, as is well known in the art. Depending upon the materials chosen, the deep well region 406 may comprise either an n-well or a p-well as determined by design requirements.

The dielectric layer 401 may be a high-K dielectric material, such as silicon oxide, silicon oxynitride, silicon nitride, an oxide, a nitrogen-containing oxide, a combination thereof, or the like. The dielectric layer 401 may have a relative permittivity value greater than about 4. Other examples of such materials include aluminum oxide, lanthanum oxide, hafnium oxide, zirconium oxide, hafnium oxynitride, or combinations thereof.

In an embodiment in which the dielectric layer 401 comprises an oxide layer, the dielectric layer 401 may be formed by any oxidation process, such as wet or dry thermal oxidation in an ambient comprising an oxide, H₂O, NO, or a combination thereof, or by chemical vapor deposition (CVD) techniques using tetra-ethyl-ortho-silicate (TEOS) and oxygen as a precursor. In an embodiment, the dielectric layer 401 is between about 8 Å to about 200 Å in thickness.

The gate electrode 404 may comprise a conductive material, such as a metal (e.g., tantalum, titanium, molybdenum, tungsten, platinum, aluminum, hafnium, ruthenium), a metal silicide (e.g., titanium silicide, cobalt silicide, nickel silicide, tantalum silicide), a metal nitride (e.g., titanium nitride, tantalum nitride), doped poly-crystalline silicon, other conductive materials, or a combination thereof. In an embodiment in which the gate electrode 404 is poly-silicon, the gate electrode 404 may be formed by depositing doped or undoped poly-silicon by low-pressure chemical vapor deposition (LPCVD) to a thickness in the range of about 400 Å to about 2,400 Å, such as about 1,400 Å.

The spacers 405 may be formed by blanket depositing a spacer layer (not shown) over the gate electrode 404 and substrate 101. The spacer layer may comprise SiN, oxynitride, SiC, SiON, oxide, and the like and may be formed by commonly used methods such as chemical vapor deposition (CVD), plasma enhanced CVD, sputter, and other methods known in the art. The spacer layer is then patterned, such as by anisotropically etching, thereby removing the spacer layer from the horizontal surfaces of the structure and forming the spacers 405 as illustrated in FIG. 4.

In an embodiment, the source/drain regions 407 are formed so as to define the channel region 408 located beneath the dielectric layer 401. The source/drain regions 407 are formed by one or more implantations of impurities, such as arsenic or boron, into the substrate 101 and may overlap the modulation regions 203. The source/drain regions 407 may be formed such that the device is either an NMOS device or a PMOS device. Because the gate electrode 404 and spacers 405 are used as masks, the source/drain regions 407 are substantially aligned with the gate electrode 404 and the respective spacers 405.

It should be noted that, though the above-described process to form source/drain regions 407 describes a specific process, one of ordinary skill in the art will realize that many other processes, steps, or the like may be used. For example, one of ordinary skill in the art will realize that a plurality of implants may be performed using various combinations of spacers and liners to form source/drain regions 407 having a specific shape or characteristic suitable for a particular purpose. Any of these processes may be used to form the source/drain regions 407, and the above description is not meant to limit the present invention to the steps presented above.

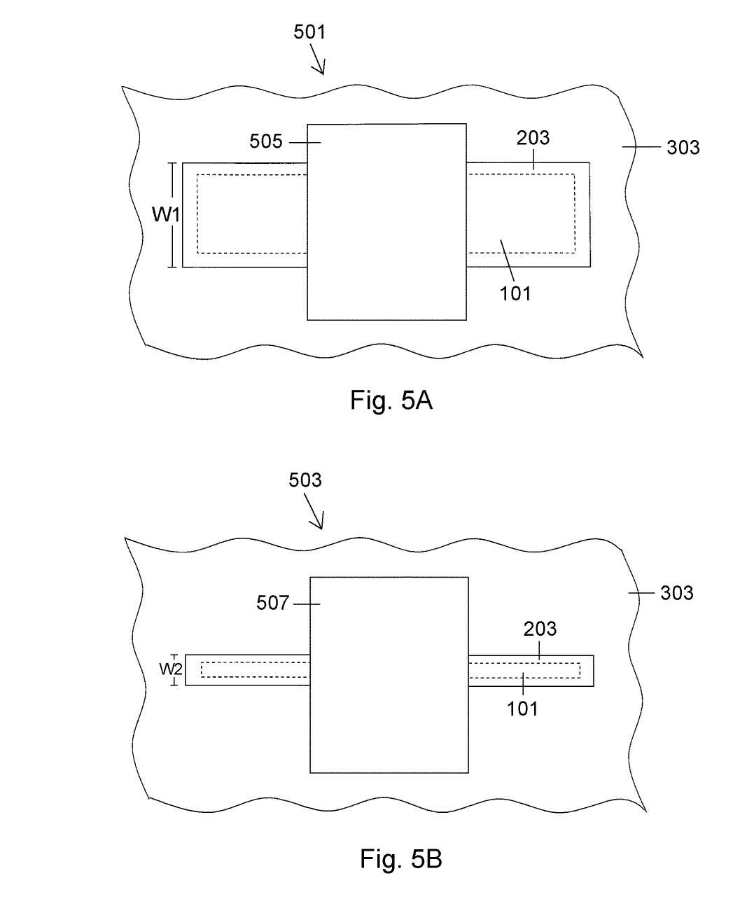

FIGS. 5A and 5B illustrate an overhead view of embodiments utilized to form a wider transistor 501, whose threshold voltage and other properties will not be significantly affected by the implant step 201, and a narrower transistor 503, whose threshold voltage and other properties may be modulated using the implant step 201, respectively. In these figures the spacers 405 have been removed to more clearly illustrate the modulation regions 203 and their relationship with a first gate width w₁ and a second gate width w₂ of the wider transistor 501 and the narrower transistor 503, respectively. Further, as can be seen in both figures, the modulation regions 203 are located adjacent to the isolation region 303 and extend inward from the isolation region 303 into the substrate 101 such that the modulation regions 203 overlap a portion of the source/drain regions 407 (not shown in FIGS. 5A-5B because these are plan views but illustrated in FIG. 4).

In FIG. 5A, the substrate 101 adjacent to the first gate 505 of a wider transistor 501 (e.g., a transistor with a first gate widths w₁ larger than about 1 μm) is hardly affected by the modulation regions 203 as formed in the implant step 201. This is because the vast majority of the substrate 101 adjacent to the first gate 505 is separated from the modulation regions 203. As such, the impacts of the implant at step 201 on the threshold voltage of the wider transistor 501 are minimal.

However, in the narrower transistor 503 with a smaller second gate width w₂ (e.g., a transistor with a second gate width w₂ less than about 0.1 μm), such as the one illustrated in FIG. 5B, similar sized modulation regions 203 would nonetheless affect a much larger percentage of the substrate 101 adjacent to the second gate 507. As such, the same implant step 201 can be used to form modulation regions 203 that affect a large percentage of the substrate 101 adjacent to the second gate 507 while only affecting a small percentage of the substrate 101 adjacent to the first gate 505 (illustrated in FIG. 5A). As such, because a large percentage of the substrate 101 adjacent to the second gate 507 is affected, the properties of the narrower transistor 503 may be significantly modulated by the modulation regions 203 while the wider transistor 501, with only a small percentage of the substrate 101 adjacent to the first gate 505 affected by the modulation region 203, is not significantly modulated. Accordingly, the abnormal increase in threshold voltage that is typically seen in the narrower transistor 503 from the short channel effects can be reduced or eliminated without significantly affecting the wider transistor 501 that is not in need of such adjustment.

Further, as one of ordinary skill in the art will recognize, the above description of “wider” and “narrower” transistors and their corresponding examples are merely illustrative examples of embodiments of the present invention. Additionally, any size transistor whose threshold voltage and other properties can be modulated using the implant step 201 may be considered a “narrow” transistor, and any size transistor whose threshold voltage and other properties are not significantly affected by the implant step 201 may be considered a “wider” transistor. Any size transistors that fit into this category are fully intended to be included within the scope of the present invention.

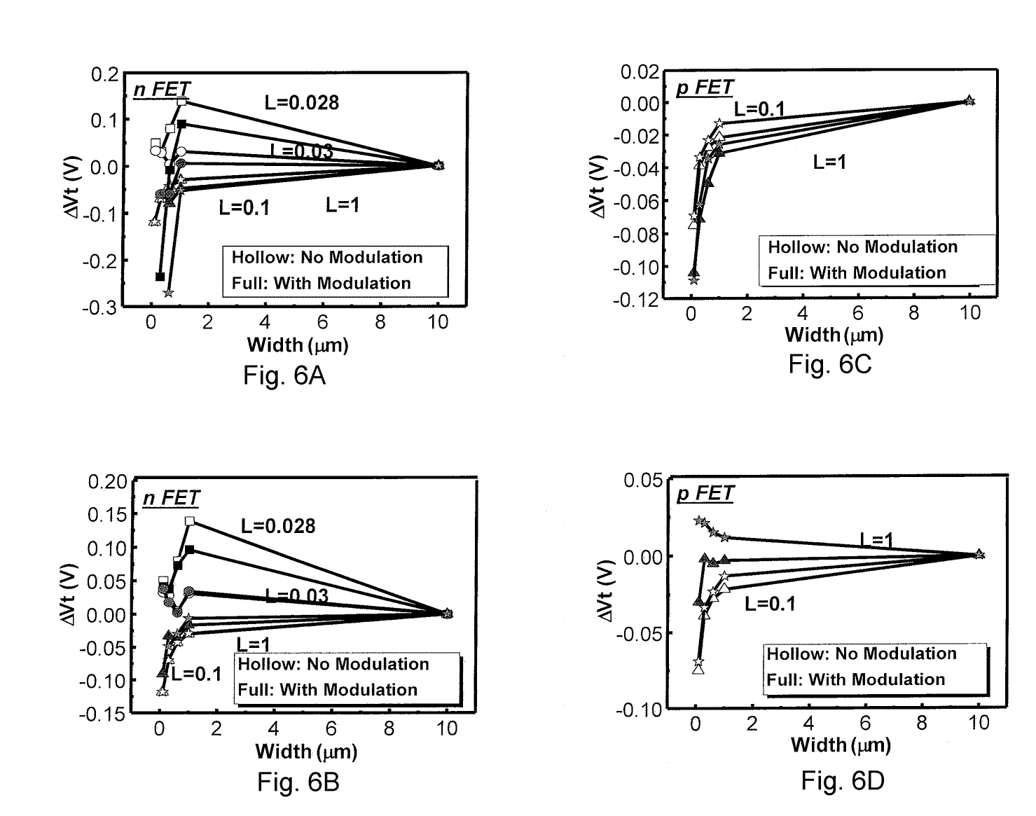

FIGS. 6A-6D illustrate adjustments that may be realized with the inclusion of the additional implantation step 201 as described above. FIGS. 6A-6B illustrate some of the adjustments that can be achieved by embodiments of the present invention for various sizes of n-type transistors using a p-type dopant and an n-type dopant, respectively. For example, FIG. 6A illustrates that, for n-type transistors with a gate width of less than about 1 μm and different gate lengths (as represented by the differently shaped data points such as the squares, circles, or stars), the threshold voltage of transistors that use a p-type modulation region (as illustrated by non-hollow data points) are reduced over similar transistors that are not modulated (as illustrated by the hollow data points). Further, FIG. 6B illustrates that, for n-type transistors with a gate width of less than about 1 μm and different gate lengths, the threshold voltage of transistors that use a n-type modulation region may be modulated over similar transistors that do not use any modulation. However, while both FIG. 6A and FIG. 6B illustrate embodiments with possible modulations of transistors with gate widths of less than about 1 μm, they also illustrate transistors with gate widths of about 10 μm that are not significantly affected by the modulation.

FIGS. 6C-6D illustrate some of the adjustments that can be achieved by embodiments of the present invention for various sizes of p-type transistors using an n-type dopant and a p-type dopant, respectively. For example, FIG. 6C illustrates that, for p-type transistors with a gate width of less than about 1 μm and different gate lengths (as represented by the differently shaped data points such as the stars or triangles), the threshold voltage of transistors that use a n-type modulation region (as illustrated by non-hollow data points) are reduced over similar transistors that are not modulated (as illustrated by the hollow data points). Further, FIG. 6D illustrates that, for p-type transistors with a gate width of less than about 1 μm and different gate lengths, the threshold voltage of transistors that use a p-type modulation region may be modulated over similar transistors that do not use any modulation. However, while both FIG. 6C and FIG. 6D illustrate embodiments with possible modulations of transistors with gate widths of less than about 1 μm, they also illustrate transistors with gate widths of about 10 μm that are not significantly affected by the modulation.

Although the present invention and its advantages have been described in detail, it should be understood that various changes, substitutions and alterations can be made herein without departing from the spirit and scope of the invention as defined by the appended claims. For example, any suitable dielectric material can be used to fill the trenches, and any suitable active devices (such as capacitors or inductors) may be formed on the active areas of the substrate.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method for manufacturing a semiconductor device, the method comprising:
providing a substrate;
forming a patterned mask over the substrate, the patterned mask exposing a portion of the substrate;
removing a portion of the substrate to form a trench;
removing a section of the patterned mask adjacent to the trench to form an exposed surface of the substrate;
implanting a first dopant with a first conductivity into the substrate;
removing the patterned mask after the implanting the first dopant; and
filling the trench with a dielectric material.

2. The method of claim 1, wherein implanting the first dopant into the substrate comprises implanting dopants at a non-perpendicular angle to the substrate.

3. The method of claim 2, wherein the angle is between about 30° and about 50°.

4. The method of claim 1, further comprising forming a gate dielectric, gate electrode, spacers, and source/drain regions.

5. The method of claim 4, wherein the gate dielectric, source/drain regions, and dielectric material define a transistor gate having a gate width less than about 1 μm.

6. The method of claim 4, wherein the source/drain regions comprise a second dopant with a second conductivity different from the first conductivity.

7. The method of claim 4, wherein the source/drain regions comprise the first dopant.

8. The method of claim 1, wherein the masking layer is silicon nitride.

9. A method of manufacturing a semiconductor device, the method comprising:
providing a substrate comprising a top surface;
forming a trench in the substrate, wherein the forming the trench comprises:
forming a masking layer over the substrate;
forming an opening through the masking layer; and
removing a portion of the substrate through the opening;
after the forming the trench, expanding the opening through the masking layer to form an exposed portion of the top surface of the substrate; and
implanting a first dopant with a first conductivity into the substrate prior to removing the masking layer.

10. The method of claim 9, further comprising:
forming a gate dielectric over the substrate;
forming a gate electrode over the gate dielectric;
forming spacers on the sidewalls of the gate dielectric and gate electrode; and
forming source/drain regions within the substrate on opposing sides of the gate dielectric.

11. The method of claim 10, wherein the source/drain regions comprise a second dopant with a second conductivity different from the first conductivity.

12. The method of claim 10, wherein the source/drain regions comprise a second dopant with the first conductivity.

13. The method of claim 9, wherein the implanting the first dopant is performed at least in part by implanting at a non-perpendicular angle to the substrate.

14. The method of claim 9, further comprising:
filling the opening with dielectric material; and
removing excess dielectric material outside of the opening.

15. A semiconductor device comprising:
a substrate with a top surface;
a first isolation region within the substrate;
a first doped region adjacent to the isolation region, the first doped region comprising a first dopant with a first conductivity and a first concentration;
a first channel region located within the substrate, the first channel region separated from the first isolation region;
a second doped region between the first doped region and the first channel region, the second doped region comprising a second dopant with a second conductivity and a second concentration less than the first concentration; and
a third doped region adjacent to the second doped region and the first channel region.

16. The semiconductor device of claim 15, wherein the first conductivity is the same as the second conductivity.

17. The semiconductor device of claim 15, wherein the first conductivity is different from the second conductivity.

18. The semiconductor device of claim 15, wherein the first doped region is part of a first transistor with a first threshold voltage.

19. The semiconductor device of claim 18, further comprising a second transistor comprising:
a second isolation region;
a second channel region;
a third doped region adjacent to the second isolation region, the third doped region comprising a third conductivity and a third concentration; and
a fourth doped region between the channel region and the third doped region, the fourth doped region comprising a fourth conductivity and a fourth concentration different from the third concentration.

20. The semiconductor device of claim 19, wherein the first transistor comprises a first threshold voltage and the second transistor comprises a second threshold voltage different from the first threshold voltage.
